(19) United States
(12) Patent Application Publication
(10) Pub. No.: US 2008/0157342 A1
(43) Pub. Date: Jul. 3, 2008

(54) Package with a marking structure and method of the same

(75) Inventor: Wen-Kun Yang, Hsin-Chu City (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/648,829

(22) Filed: Jan. 3, 2007

(51) Int. Cl. H01L 23/522; H01L 21/98

(52) U.S. Cl. 257/700; 438/641; 257/E23.145; 257/E21.705

(57) ABSTRACT

The present invention provides a semiconductor device package with a metal marking structure comprising a substrate with a die receiving cavity formed within an upper surface of the substrate and a through hole structure formed there through, wherein a terminal pad is formed under a lower surface of the substrate and a conductive trace formed on the lower surface of the substrate; a die attached within the die receiving cavity and having a plurality of bonding pads formed thereon; a first dielectric layer formed on the die and the substrate to expose the surface of the bonding pads and the through hole structure; a redistribution layer formed on the first dielectric layer to couple the bonding pads and the through hole structure; a second dielectric layer formed on the first dielectric layer and the redistribution layer trace; a metal marking layer formed on the second dielectric layer; and a heat sink layer formed on the metal marking layer.

### BACKGROUND OF THE INVENTION

1. Field of the Invention

This invention relates to a package structure, and more particularly to a package with a marking structure of panel scale package-chip scale package (PSP-CSP) and method of the same, the marking structure can prevent the structure form EM (electromagnetic) radiation interference and offering better thermal management.

2. Description of the Prior Art

In recent years, the high-technology electronics manufacturing industries launch more feature-packed and humanized electronic products. Rapid development of semiconductor technology has led to rapid progress of a reduction in size of semiconductor packages, the adoption of multi-pin, the adoption of fine pitch, the minimization of electronic components and the like. The purposes and the advantages of wafer level package includes decreasing the production cost, decreasing the effect caused by the parasitic capacitance and parasitic inductance by using the shorter conductive line path, acquiring better SNR (i.e. signal to noise ratio).

The chip-scale package (CSP) has been conventionally formed by a method in which a semiconductor wafer is cut into semiconductor chips, then the semiconductor chips are mounted on a base substrate serving as a package base at predetermined positions and bonded thereto, and they are collectively sealed with a resin, thereafter the sealing resin and the base substrate are cut into pieces together at the parts between the semiconductor chips. In another conventional method, a semiconductor wafer (not being cut into semiconductor chips yet) is mounted on a base substrate and bonded thereto, then the semiconductor wafer and the base substrate are cut simultaneously, and the cut and divided semiconductor chips and package bases are sealed with a resin.

Further, the operability, performance, and life of an IC chip are greatly affected by its circuit design, wafer manufacturing, and chip packaging. For this present invention, the focus will be on chip packaging technique. Since the features and speed of IC chips are increasing rapidly, the need for increasing the conductivity of the circuitry is necessary so that the signal delay and attenuation of the dies to the external circuitry are reduced. A chip package that allows good thermal dissipation and protection of the IC chips with a small overall dimension of the package is also necessary for higher performance chips. These are the goals to be achieved in chip packaging.

Moreover, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip ball grid array (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

In the manufacturing method, wafer level chip scale package (WLCSP) is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices. Further, WLCSP has an advantage of being able to print the redistribution circuit directly on the die by using the peripheral area of the die as the bonding points. It is achieved by redistributing an area array on the surface of the die, which can fully utilize the entire area of the die. The bonding points are located on the redistribution circuit by forming flip chip bumps so the bottom side of the die connects directly to the printed circuit board (PCB) with micro-spaced bonding points.

Although WLCSP can greatly reduce the signal path distance, it is still very difficult to accommodate all the bonding points on the die surface as the integration of die and internal components gets higher. The pin count on the die increases as integration gets higher so the redistribution of pins in an area array is difficult to achieve. Even if the redistribution of pins is successful, the distance between pins will be too small to meet the pitch of a printed circuit board (PCB). That is to say, such process and structure of prior art will suffer yield and reliability issues owing to the huge size of package. The further disadvantage of former method are higher costs and time-consuming for manufacture.

In view of the aforementioned, the present invention provides a new structure and method for a marking structure of that can prevent form wave interference for a panel scale package-chip scale package (PSP-CSP) to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a semiconductor device package with a marking structure of PSP-CSP and method of the same, which can allow protect the structure from EM (electromagnetic) radiation interference.

Another objective of the present invention is to provide a semiconductor device package with a marking structure of PSP-CSP and method of the same, which can allow good appearance of the top surface of device.

Still another objective of the present invention is to provide a semiconductor device package with a marking structure of PSP-CSP and method of the same, which can connect to ground for heat exhaustion.

Yet another objective of the present invention is to provide a semiconductor device package with a marking structure of PSP-CSP and method of the same, which can improve the ground shielding performance.

Another objective of the present invention is to provide a semiconductor device package with a marking structure of PSP-CSP and method of the same, which can protect the redistribution layer (RDL) circuit of device.

The present invention provides a semiconductor device package with a marking structure comprising a substrate with a die receiving cavity formed within an upper surface of the substrate and a through hole structure formed there through, wherein a terminal pad is formed under a lower surface of the substrate and a conductive trace formed on the lower surface of the substrate; a die attached within the die receiving cavity and having a plurality of bonding pads formed thereon; a first dielectric layer formed on the die and the substrate to expose the surface of the bonding pads and the through hole structure; a redistribution layer formed on the first dielectric layer to couple the bonding pads and the through hole structure; a second dielectric layer formed on the first dielectric layer and the redistribution layer trace; a metal marking layer formed on the second dielectric layer; and a heat sink layer formed on the metal marking layer.

The present invention provides a method for forming a semiconductor device package of a marking structure comprising preparing a substrate with a die receiving cavity formed with an upper surface of the substrate and a through hole structure formed there through, wherein a terminal pad is formed under the through hole structure and the substrate includes a conductive trace formed on a lower surface of the substrate; attaching a die within the die receiving cavity, wherein the die having a plurality of bonding pads formed thereon; forming a first dielectric layer on the substrate and the die to expose the bonding pads and the through hole structure; forming a redistribution layer on the first dielectric layer to couple the bonding pads and the through hole structure; forming a second dielectric layer on the redistribution layer; forming a metal marking layer on the second dielectric layer; and forming a heat sink layer on the metal marking layer.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates is a cross-section diagram of a semiconductor device package with a marking structure of panel scale package chip scale package (PSP-CSP) according to the present invention;

FIG. 2 illustrates a top view diagram of a semiconductor device package with a marking structure of panel scale package chip scale package (PSP-CSP) according to the present invention; and

FIG. 3 illustrates a flow chart of a method of forming a semiconductor device package with a marking structure of panel scale package chip scale package (PSP-CSP) according to the present invention.

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

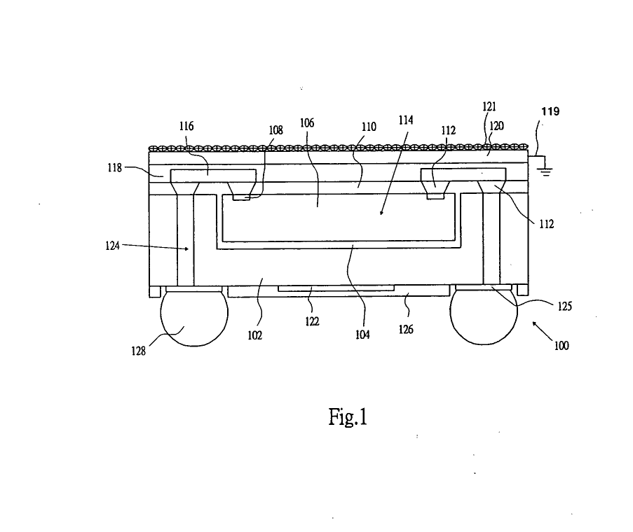

Referring to FIG. 1, it is a cross-section diagram of a semiconductor device package with a marking structure 100 of panel scale package chip scale package (PSP-CSP) according to the present invention. The package with a marking structure 100 comprises a substrate 102, a die receiving cavity 114, a through hole 124, an adhesion material 104, a die 106, a plurality of bonding pads 108, a first dielectric layer 110, via conductive layers 112, a redistribution layer (RDL) 116, a second dielectric layer 118, a metal marking layer 120, a heat sink layer 121, a conductive trace 122, protection layer 126 and a plurality of soldering bumps 128.

In FIG. 1, the substrate 102 has a die receiving cavity 114 formed within an upper surface of the substrate 102 to receive a die 106. A plurality of through hole structures 124 are created through the substrate 102 from the upper surface to lower surface of the substrate 102. The plurality of through hole structures 124 are filled by a conductive material for electrical communication. The terminal pads 125 are formed under a lower surface of the substrate 102, and connected to the through hole structure 124. The conductive trace 122 (wiring circuit) is configured on the lower surface of the substrate 102.

Further, a die 106 having a plurality of bonding pads 108 is attached within the die receiving cavity 114, and the bonding pads 108 are formed within the upper side of the die 106, so that the surface of the bonding pads 108 are exposed before forming redistribution layer (RDL) 116. After forming the first dielectric layer 110 on the die 106 and the substrate 102, the partial region of the first dielectric layer 110 is removed to expose the surface of the bonding pads 108 and the through hole structure 124. The via conductive layers 112 are filled on the exposed surface of the bonding pads 108 and the through hole structure 124 to electrically connect with each other. Then, the redistribution layer 116 is formed on the via conductive layers 112 and the first dielectric layer 110. That is to say, the regions between the via conductive layer 112 form on the surface of the bonding pads 108 and through hole structure 124 are covered by the redistribution layer 116, and therefore the redistribution layer 116 can connect the via conductive layers 112 which are formed on the surface of the bonding pads 108 and through hole structure 124.

Next, a second dielectric layer 118 is formed on the first dielectric layer 110 to cover the redistribution layer 116. Subsequently, the metal marking layer 120 is formed on the second dielectric layer 118, and next the heat sink layer 121 is formed on the metal marking layer 120. The plurality of soldering bumps 128 are formed on the terminal pads 125, and therefore the plurality of soldering bumps 128 can be electrically connected with the bonding pads 108 through the through hole structure 124.

In one embodiment, the package with a marking structure 100 further comprises an adhesion material 104 within and surrounding the die receiving cavity 114 for attaching the die 106.

In one embodiment, the material of the substrate 102 includes epoxy type FR5, FR4 or BT (Bismaleimide triazine epoxy). The material of the substrate 102 also can be metal, alloy, glass, silicon, ceramic or print circuit board (PCB). The alloy further includes alloy 42 (42% Ni-58% Fe) or Kovar (29% Ni-17% Co-54% Fe). Further, the alloy metal is preferably composed by alloy 42 that is a nickel iron alloy whose coefficient of expansion makes it suitable for joining to silicon chips in miniature electronic circuits and consists of nickel 42% and ferrous (iron) 58%. The alloy metal also can be composed by Kovar which consists of nickel 29%, cobalt 17% and ferrous (iron) 54%.

In one embodiment, the material of the first dielectric layer 110 and second dielectric layer 118 includes benzocyclobutene (BCB), Siloxane polymer (SINR) or polyimide (PI). The material of the redistribution layer 116 is made from an alloy comprising Ti/Cu/Au alloy or Ti/Cu/Ni/Au alloy.

In one embodiment, the material of the metal marking layer 120 includes metal to protect the package from EM radiation interference. It is noted that the materials of the present invention are only used to illustrate rather than limit the present invention.

In one embodiment, the material of the heat sink layer 121 includes the molecular cooling fan coating on metal marking layer 120 to enhance the thermal management.

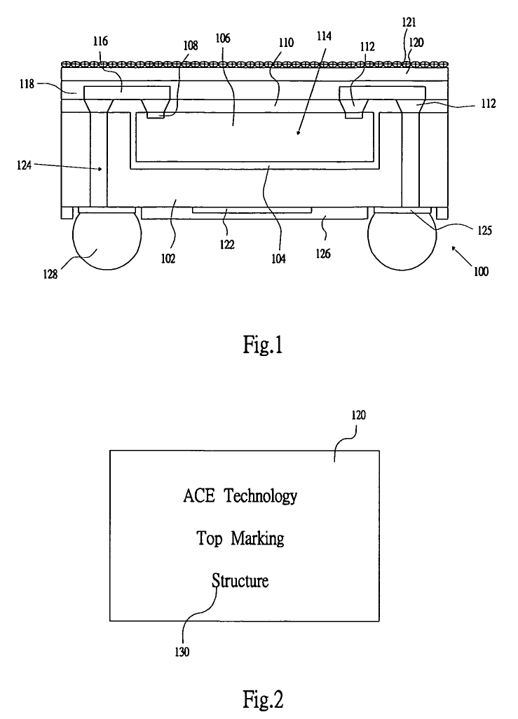

Refer to FIG. 2, it illustrates a top view diagram of a semiconductor device package with a marking structure 100 of panel scale package chip scale package (PSP-CSP) according to the present invention. The package with a marking structure 100 further comprises characters, texts, words, pattern or logo 130 marked on the top surface of the structure 100.

In one embodiment, the present invention further comprises a ground signal connected to the metal marking layer 120 as ground shielding and heat dissipation.

According the aspect of the present invention, after completing the PSP-CSP built-up layer structure, a seed metal layer (not shown) is sputtering on the second dielectric layer 118, that is to say, the seed metal layer is sputtering on the top surface of the structure. The material of the seed metal layer includes Ti/Cu. Next, coating the photo resist layer (not shown) on the seed metal layer, and photo masking the photo resist layer to form the plurality of characters 130. A Cu/Au film is electroplating on the surface of the package with a marking structure 100. Preferably, the thickness of the Cu/Au film is approximately around 6-20 μm. Then, the photo resist layer is stripped form the top surface the package with a marking structure 100. Optionally, the seed metal layer is removed by a wet etching method. Then, to coat the heat sink materials 121 (prefer molecular cooling fan) on top of metal marking layer 120, the thickness of heat sink layer 121 is around 10 μm.

Next, the metal marking layer 120 and heat sink layer 121 are formed on the top surface of the package with a marking structure 100. In other words, the top surface of the package with a marking structure 100 is covered by the metal marking layer 120 and heat sink layer 121. Optionally, an Au film is plating on the metal marking layer 120 without cover the plurality of characters 130. It is noted that other various metal also can be used for plating on the metal marking layer 120.

In one embodiment, the plurality of characters texts, words, pattern or logo 130 includes, but not limited to, various trademark, pattern or mark.

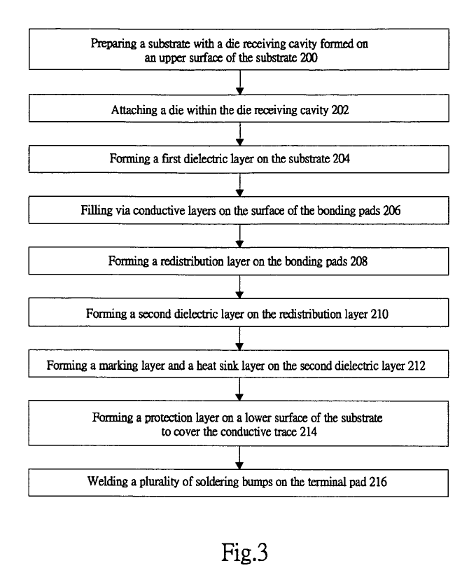

According to the aspect of the present invention, the present invention further provides a method for forming a package with a marking structure 100. FIG. 3 illustrates a flow chart of a method of forming a package with a marking structure 100 according to the present invention. The steps are illustrated as follows.

First, preparing a substrate 102 with a die receiving cavity 114 formed with an upper surface of the substrate 102 and a through hole structure 124 formed there through, wherein a terminal pad 125 is formed under the through hole structure 124 and the substrate 102 includes a conductive trace 122 formed on a lower surface of the substrate 102 in step 200. Next, a die 106 is attached within the die receiving cavity 114, and the die 106 having a plurality of bonding pads 108 formed thereon in step 202. A first dielectric layer 110 is coating on the substrate 102 and the die 106 to expose the bonding pads 108 and the through hole structure 124 in step 204. The via conductive layers 112 are filled on the exposed surface of the bonding pads 108 and the through hole structure 124 in step 206.

Subsequently, a redistribution layer 116 is formed on the bonding pads 108 and the through hole structure 124 to connect with each other in step 208. A second dielectric layer 118 is formed on the redistribution layer 116 in step 210. Next, a metal marking layer 120 and a heat sink layer 121 are formed on the second dielectric layer 118 in step 212. A protection layer 126 is formed on a lower surface of the substrate 102 to cover the conductive trace 122 in step 214. Then, a plurality of soldering bumps 128 is welded on the terminal pad 125 in step 216.

It is noted that the material and the arrangement of the structure are illustrated to describe but not to limit the present invention. The material and the arrangement of the structure can be modified according to the requirements of different conductions.

According to the aspect of the present invention, the present invention provides a metal marking structure, which allows protecting the structure from EM radiation interference and good appearance of the top surface of device. Further, the present invention provides a fan out type structure that can connect to ground for heat exhaustion and improve the ground shielding performance. The present invention further provides a new structure that has a die receiving cavity for attaching the die, and therefore can also minimize the size of chip scale package structure. Moreover, the present invention provides a metal marking structure and method of the same, which can protect the redistribution layer (RDL) circuit of device. Therefore, the super thin chip scale structure and method of the same disclosed by the present invention can provide unexpected effect than prior art, and solve the problems of prior art. The method may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

1. A semiconductor device package with a marking structure, comprising:
a substrate with a die receiving cavity formed within an upper surface of said substrate and a through hole structure formed there through, wherein a terminal pad is formed under a lower surface of said substrate and a conductive trace formed on the lower surface of said substrate;
a die attached within said die receiving cavity and having a plurality of bonding pads formed thereon;
a first dielectric layer formed on said die and said substrate to expose the surface of said bonding pads and said through hole structure;
a redistribution layer formed on said first dielectric layer to couple said bonding pads and said through hole structure;
a second dielectric layer formed on said first dielectric layer and said redistribution layer; and
a metal marking layer formed on said second dielectric layer.

2. The structure in claim 1, further comprising a plurality of soldering bumps formed on said terminal pads; wherein said plurality of soldering bumps are electrically connected with said bonding pads through said through hole structure.

3. The structure in claim 1, further comprising a protection layer formed on the lower surface of said substrate to cover said conductive trace.

4. The structure in claim 1, further comprising a heat sink layer formed on said metal marking layer.

5. The structure in claim 4, wherein material of said heat sink layer includes molecular cooling fan to enhance said heat dissipation.

6. The structure in claim 1, further comprising an adhesion material surrounding said die receiving cavity for attaching said die.

7. The structure in claim 1, wherein material of said substrate includes epoxy type FR5, FR4 or BT (Bismaleimide triazine).

8. The structure in claim 1, wherein material of said substrate includes metal, alloy, glass, silicon, ceramic or print circuit board (PCB).

9. The structure in claim 8, wherein said alloy includes alloy 42 (42%Ni-58%Fe) or Kovar (29%Ni-17%Co-54%Fe).

10. The structure in claim 1, wherein said through hole structure is filled by a conductive material.

11. The structure in claim 1, wherein material of said first dielectric layer and second dielectric layer includes benzocyclobutene (BCB), Siloxane polymer (SINR) or polyimide (PI).

12. The structure in claim 1, wherein said redistribution layer is made from an alloy comprising Ti/Cu/Au alloy or Ti/Cu/Ni/Au alloy.

13. The structure in claim 1, wherein said redistribution layer communicates to said terminal pad downwardly via said through hole structure.

14. The structure in claim 1, wherein material of said marking layer include metal to protect said package from EM radiation interference.

15. The structure in claim 1, further comprising a seed metal layer sputtered on said first and second dielectric layer.

16. The structure in claim 1, further comprising a character, a text, a word, a pattern or a logo plated on said metal marking layer.

17. The structure in claim 1, further comprising a ground signal connected to said metal marking layer as ground shielding and heat dissipation.

18. A method for forming a semiconductor device package with a marking structure, comprising:
preparing a substrate with a die receiving cavity formed on an upper surface of said substrate and a through hole structure formed there through, wherein a terminal pad is formed under said through hole structure and said substrate includes a conductive trace formed on a lower surface of said substrate;
attaching a die within said die receiving cavity, wherein said die having a plurality of bonding pads formed thereon;
forming a first dielectric layer on said substrate and said die to expose said bonding pads and said through hole structure;
forming a redistribution layer on said first dielectric layer to couple said bonding pads and said through hole structure;
forming a second dielectric layer on said redistribution layer and said first dielectric layer;
forming a metal marking layer on said second dielectric layer;
applying a photo resist layer on said metal marking layer for forming the characters and then removed.

19. The method in claim 18, further comprising a step of welding a plurality of soldering bumps on said terminal pad.

20. The method in claim 18, further comprising a step of coating a heat sink material on said metal marking layer.

21. The method in claim 18, further comprising a step of attaching an adhesion material surrounding said die receiving cavity.

22. The method in claim 18, further comprising a step of connecting a ground signal to said metal marking layer.

23. The method in claim 18, further comprising a step of plating characters, texts, words, pattern or logo on said metal marking layer.

24. The method in claim 18, further comprising a step of sputtering a seed metal layer on said first and second dielectric layer.
